(19) United States
(12) Patent Application Publication
(10) Pub. No.: US 2014/0073070 A1
(43) Pub. Date: Mar. 13, 2014

(54) MANUFACTURING METHOD OF SEMICONDUCTOR DEVICE, SUPPORTING SUBSTRATE, AND SEMICONDUCTOR MANUFACTURING APPARATUS

(71) Applicant: KABUSHIKI KAISHA TOSHIBA, Tokyo (JP)

(72) Inventor: Hiroshi TSUJII, Ishikawa-ken (JP)

(73) Assignee: KABUSHIKI KAISHA TOSHIBA, Tokyo (JP)

(21) Appl. No.: 14/018,862

(22) Filed: Sep. 5, 2013

(30) Foreign Application Priority Data
Sep. 13, 2012 (JP) 2012-201132

(51) Int. Cl. H01L 21/66; G01R 31/26; H01L 21/687; H01L 21/67

(52) U.S. Cl. CPC H01L 22/14; H01L 21/67242; G01R 31/2601; H01L 21/68742
USPC 438/17; 428/131; 324/756.01; 269/14

(57) ABSTRACT

A method for fabricating a semiconductor device comprising: a first process for attaching a first supporting substrate having a plurality of through holes to a semiconductor substrate having a first surface and a second surface, so that each of the through holes is opposed to a semiconductor device formed in the semiconductor substrate; a second process for contacting probes of an electric characteristic inspection apparatus with a first electrode formed on the first surface, and a second electrode formed on the second surface via the through hole; and a third process for measuring electric characteristic of the semiconductor device.

### CROSS-REFERENCE TO RELATED APPLICATIONS

This application is based upon and claims the benefit of priority from the prior Japanese Patent Application No. 2012-201132, filed Sep. 13, 2012, the entire contents of which are incorporated herein by reference.

### FIELD

Embodiments described herein relate to a manufacturing method of semiconductor device, a supporting substrate, and a semiconductor manufacturing apparatus.

### BACKGROUND

In a vertical semiconductor device such as a discrete semiconductor, a semiconductor substrate (hereinafter referred to as a wafer) is reduced in thickness by grinding, polishing, etching, or the like from the its surface, and then various process treatments are applied to a back surface of the wafer. After the process treatments, in general, electrical characteristics of the semiconductor device are inspected and the semiconductor devices are divided into discrete pieces. However, the wafer is significantly warped by lowering of the strength due to the reduction in thickness of the wafer, stress due to a structure of the semiconductor device formed on the wafer, and the like. Thus, it is difficult to convey the wafer. Moreover, failure (cracking and breaking, for example) in the conveyance and processing of the wafer easily occurs.

Thus, there has been adopted a method in which various process treatments are applied on the back surface of the wafer. The process treatments are practiced in such a state that a supporting substrate is attached to a front surface of the wafer. Meanwhile, electrical characteristic inspection is practiced after the various process treatments applied to the back surface of the wafer and the formation of a back surface electrode on the back surface of the wafer. It is necessary to bring a probe of an electric characteristic inspection apparatus into contact with a first electrode on the front surface side of the wafer. And it is necessary to bring a test stage of the electric characteristic inspection apparatus into contact with the second electrode on the back surface side of the wafer.

However, in such a state that the supporting substrate (a glass substrate, for example) is applied on the front surface of the wafer, the probe of the inspection apparatus can't be brought into contact with the first electrode. Thus, when the electrical characteristic of the semiconductor device is inspected, it is necessary to remove the supporting substrate applied on the front surface of the wafer to expose the first electrode. Generally, the supporting substrate is removed from the wafer after while the wafer is mounted on a dicing sheet. However, when the supporting substrate is removed, the strength of the wafer is required to be maintained and thus the dicing sheet can't be removed.

Thus, there has been proposed that a treatment tray (reinforcement substrate) having sucker holes due to suck the semiconductor device sucks the semiconductor substrate, the semiconductor substrate is diced, and the semiconductor device is divided into discrete pieces.

### DESCRIPTION OF THE DRAWINGS

FIGS. 1A to 1C show respectively an overhead view, a plan view, and a cross-sectional view showing a configuration of a supporting substrate according to an embodiment:

FIG. 2 shows a plan of the supporting substrate applied to a wafer: and

FIGS. 3A to 3F show cross-sectional views showing a method for fabricating a semiconductor device using the supporting substrate.

### DETAILED DESCRIPTION

Hereinafter, an embodiment will be described in detail with reference to the drawings.

### Embodiment

<Configuration of Supporting Substrate 100>

A configuration of a supporting substrate 100 (first supporting substrate) will be described.

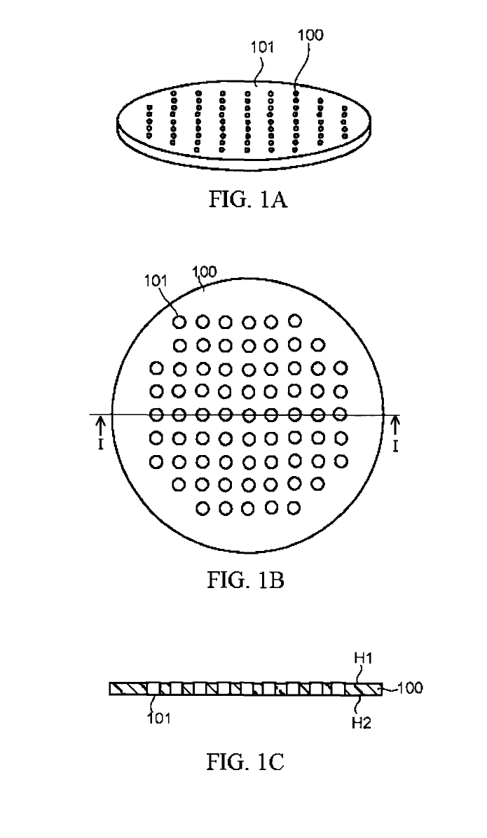

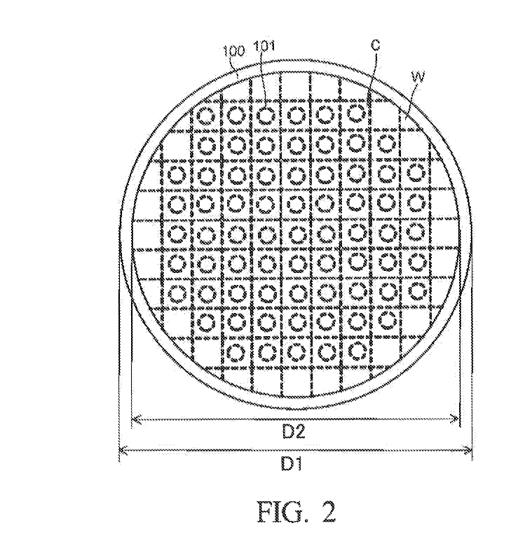

FIGS. 1A to 1C show respectively an overhead view, a plan view, and a cross-sectional view showing a configuration of a supporting substrate 100 according to an embodiment. FIG. 1A shows an overhead view of the supporting substrate 100. FIG. 1B shows a plan view of the supporting substrate 100. FIG. 1C shows a cross-sectional view of the supporting substrate 100 taken along I-I line of FIG. 1B. FIG. 2 shows a plan of the supporting substrate 100 applied to a wafer W. Hereinafter, configuration of the supporting substrate 100 according to the embodiment will be described in detail with reference to FIGS. 1A to 1C and FIG. 2.

When a back surface (second surface) of a semiconductor substrate W (hereinafter referred to as a wafer W) on which the semiconductor device is formed is polished to be reduced in thickness, or after the wafer W is reduced in thickness, the supporting substrate 100 is used as a reinforcing plate of the wafer W until inspection of the electric characteristics of the semiconductor device formed in the wafer W by dicing.

The supporting substrate 100 has a plurality of through holes 101 going through from a front surface H1 of that to a back surface H2 of that. The through holes 101 are formed at a position falling square semiconductor devices C to be made in wafer W when the support substrate 100 is applied the wafer W. In other words, the through holes 101 are formed to accord the semiconductor devices C formed in the wafer W.

The supporting substrate 100 is formed by being cut out from a glass or metal plate. An outer diameter D1 of the supporting substrate 100 and the diameter D2 of the wafer W to be supported are just about same. Specifically, it is preferable that the outer diameter D1 of the supporting substrate 100 is larger by approximately 20 mm.

For example, when the diameter D2 of the wafer W is 200 mm, it is preferable that the outer diameter D1 of the supporting substrate 100 is approximately 220 mm. The outer diameter D1 of the supporting substrate 100 is made larger than the diameter D2 of the wafer W, because it is prevented the wafer W from chipping when an edge of the wafer W touches conveyance robot and the like.

<Manufacturing Method of Semiconductor Device, and Semiconductor Manufacturing Apparatus>

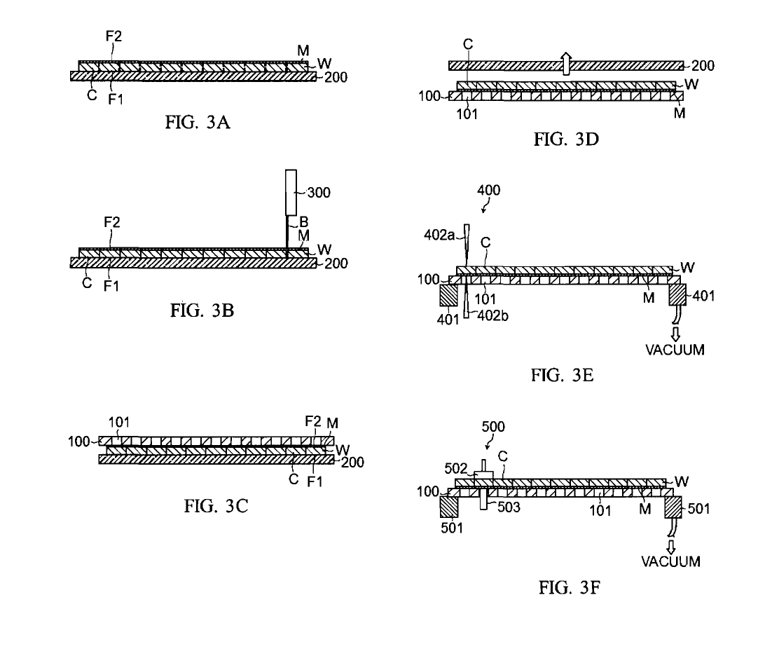

FIGS. 3A to 3F show cross-sectional views showing a method for fabricating a semiconductor device using the supporting substrate. Hereinafter, the fabricating method of the semiconductor device and the semiconductor manufacturing apparatus will be described with reference to FIGS. 3A to 3F. In addition, below explanation of the fabricating method of the semiconductor device and the semiconductor manufacturing apparatus is after process such as thinning of the wafer W, ion implantation, diffusion (laser annealing), and formation of a back surface electrode M (sputtering using PVD (physical vapor deposition) apparatus).

A plurality of semiconductor devices C is formed on a front surface F (first surface) of the wafer W, and a supporting substrate 200 (second supporting substrate) is applied on a back surface F2 (second surface) of the wafer W formed a back metal M (shown in FIG. 3A). The back metal M is back surface electrode of individual semiconductor device C.

In a state that the supporting substrate 200 is applied on the front surface F1 of the wafer W, the wafer W is diced by using a dicing unit 300 (shown in FIG. 3B). By the dicing process, the semiconductor device C is divided into discrete pieces. The wafer W is diced from the back surface F2 of the wafer W. In FIG. 3B, the wafer W is diced by using a blade B. But the wafer W may be diced by using laser and divided into discrete pieces.

The supporting substrate 100 described by using FIG. 1 is applied on the back surface electrode M formed on the back surface F2 of the wafer W (shown in FIG. 3C). The through holes 101 formed in the supporting substrate 100 is fell on the semiconductor devices C when the supporting substrate 100 is applied on the back surface electrode M formed on the back surface F2 of the wafer W so as to fall

In a state that the supporting substrate 100 is applied on the back surface F2 of the wafer W and the supporting substrate 200 is applied on the front surface F1 of the wafer W, up and down of the wafer W is reversed and the supporting substrate 200 applied on the front surface F1 of the wafer W is removed (shown in FIG. 3D).

To hold the wafer W applied the supporting substrate 100 on the back surface, the edge of the supporting substrate 100 is sucked into a hold mechanics 401 of an electric characteristic test device 400 (semiconductor manufacturing apparatus). Next, so as to measure electric characteristics of the semiconductor devices C, a probe 402a (first probe) of the electric characteristic test device 400 contacts with a front surface electrode (not shown) of the semiconductor device C forming on the front surface Fl of the wafer W exposing by removing the supporting substrate 200. In addition, so as to measure electric characteristics of the semiconductor devices C, a probe 402b (second probe) of the electric characteristic test device 400 contacts with a back surface metal M (back surface electrode) of the semiconductor device C via the through holes 101 of the supporting substrate 100 (shown in FIG. 3E).

A pickup device 500 (semiconductor manufacturing apparatus) picks only a plurality of good semiconductor devices C after the electric characteristic test of the semiconductor devices C (shown in FIG. 3F). First, to hold the wafer W finishing the electric characteristic test, the edge of the supporting substrate 100 is sucked into a hold mechanics 501 of the pickup device 500. Next, a collet 502 of the pickup device 500 sucks a surface of the semiconductor device C (the back surface F2 of the wafer W). Finally, via the through holes 101 of the supporting substrate 100, the semiconductor device C sucked by the collet 502 is knocked up by a knocking up pin 503 from the front surface F1 side of the wafer W.

When area that the collet 502 sucks the semiconductor device C is large, it is possible to buffer impulse to the semiconductor device C. Therefore, it is preferable that size and shape of a sucking surface of the collet 502 are same as size and shape of sucked semiconductor device C.

As described above, in the embodiment, the support substrate 100 having the through holes 101 forming at a position falling the semiconductor devices C is used when the support substrate 100 is applied the wafer W. Therefore, the process from the reduction in thickness of the wafer W to the inspection of the electric characteristics of the semiconductor device can be performed in such a state that the wafer W is always reinforced.

Size and shape of a sucking surface of the collet 502 are same as size and shape of sucked semiconductor device C. Therefore, in pickup process, it is possible to buffer impulse to the semiconductor device C.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for fabricating a semiconductor device comprising:
a first process for attaching a first supporting substrate having a plurality of through holes to a semiconductor substrate having a first surface and a second surface, so that each of the through holes is opposed to a semiconductor device formed in the semiconductor substrate;
a second process for contacting probes of an electric characteristic inspection apparatus with a first electrode formed on the first surface, and a second electrode formed on the second surface via the through hole; and
a third process for measuring electric characteristic of the semiconductor device.

2. The method for fabricating a semiconductor device according to claim 1, the method further comprising:
a fourth process for attaching a second supporting substrate to the first surface before the first supporting substrate being applied with the second surface; and
a fifth process for removing the second supporting substrate.

3. The method for fabricating a semiconductor device according to claim 1, the method further comprising:
a sixth process for sucking a collet on the first surface after electric characteristic measurement; and
a seventh process for knocking up a knocking up pin on the semiconductor device via the through hole.

4. A supporting substrate comprising:
each of through holes, formed in a supporting substrate, opposing to a semiconductor device formed in a semiconductor substrate.

5. The supporting substrate according to claim 4, wherein an outer diameter of the supporting substrate is larger than an outer diameter of the semiconductor substrate.

6. A supporting manufacturing apparatus comprising:
a hold mechanics holding a semiconductor substrate, having a first surface and second surface, attaching a supporting substrate described in claim 4;
a first probe contacting with a first electrode formed on the first surface; and
a second probe contacting with a second electrode formed on the second surface via the through hole.

7. The supporting manufacturing apparatus according to claim 6, further comprising:
a knocking up pin knocks up a semiconductor device formed in the semiconductor substrate via the through hole; and
a collet picks up knocked up the semiconductor device.
